(19) United States
(12) Patent Application Publication
(10) Pub. No.: US 2026/0093185 A1
(43) Pub. Date: Apr. 2, 2026

(54) Methods And Systems For In-Situ Discovery Of Illumination Angles In Semiconductor Measurements

(71) Applicant: KLA Corporation, Milpitas, CA (US)

(72) Inventors: Boxue Chen, San Jose, CA (US); Nir Yefet, Nahariya (IL); James A. Real, Oakland, CA (US); Tianhan Wang, Milpitas, CA (US); Guanggi Zhang, Campbell, CA (US); Christopher Liman, San Jose, CA (US); Yung-Yi Lin, San Jose, CA (US); Huy M. Nguyen, Los Altos, CA (US); Robert Press, San Jose, CA (US)

(21) Appl. No.: 19/326,543

(22) Filed: Sep. 11, 2025

Related U.S. Application Data
(60) Provisional application No. 63/701,575, filed on Sep. 30, 2024.

(51) Int. Cl. G03F 7/00

(52) U.S. Cl. CPC G03F 7/70625; G03F 7/7025; G03F 7/706841; G03F 7/70758; G03F 7/70775

(57) ABSTRACT

Methods and systems for compensating for uncertainty in illumination angle of incidence to enable accurate measurements of semiconductor structures are described herein. In one aspect, measurements are performed at one or more nominal angles of incidence, an actual angle of incidence corresponding to each measurement is estimated, and a value of a parameter of interest characterizing a measured structure is estimated based at least in part on the collected measurement data and the actual angle of incidence. In some examples, an actual angle of incidence is directly measured. In some other examples, an actual angle of incidence is estimated from measurement data collected over a range of nominal illumination angles of incidence. In some other examples, an actual angle of incidence with respect to a tilted structure is estimated from measurement data collected over a range of nominal illumination angles of incidence.

### CROSS REFERENCE TO RELATED APPLICATION

The present application for patent claims priority under 35 U.S.C. § 119 from U.S. provisional patent application Ser. No. 63/701,575, entitled “Flexible Measurement Recipes for Fast and Accurate Semiconductor Metrology,” filed Sep. 30, 2024, the subject matter of which is incorporated herein by reference in its entirety.

### TECHNICAL FIELD

The described embodiments relate to metrology and inspection systems and methods, and more particularly to methods and systems with improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology and inspection processes are used at various steps during a semiconductor manufacturing process to detect defects on wafers to promote higher yield. Available semiconductor measurement systems include film and critical dimension (CD) metrology, overlay metrology, bare wafer and product wafer inspection, etc. In many examples, X-Ray and optical metrology techniques offer the potential for high throughput without the risk of sample destruction. A number of X-ray and optical metrology based techniques including scatterometry, reflectometry, and ellipsometry implementations and associated analysis algorithms are commonly used to characterize critical dimensions, film thicknesses, composition, overlay and other parameters of nanoscale structures.

In typical operational scenarios, a user defines a measurement recipe including a desired angle of incidence or set of desired angles of incidence associated with a particular measurement. In one example, a user of a spectroscopic ellipsometer metrology system manufactured by KLA Corporation (USA) selects one or more desired angles of incidence from a set of available angles of incidence at 59 degrees, 65 degrees, and 71 degrees from the surface normal. In other examples, a user of a transmission, small-angle x-ray scatterometry metrology system manufactured by KLA Corporation (USA) defines a list of desired angles of incidence and corresponding exposure times associated with a set of measurements.

In general, wafers are positioned in the optical path of a metrology and inspection system during measurement. However, wafers and the positioning systems employed to locate the wafer are not perfectly flat. Thus, the orientation of the wafer surface at the measurement spot varies depending on the lateral position, i.e., x-y position, of the wafer with respect to the measurement system. In some examples, variations in wafer tilt introduce variations in the illumination angle of incidence. This introduces undesirable variation in measurement signals. A critical challenge faced in the development of many metrology and inspection systems is performing accurate measurements with uncertainty in the illumination angle of incidence.

Uncertainty in the illumination angle of incidence arises for various reasons. In one example, the wafer positioning stage employed to locate the wafer in the optical path of a measurement system is constructed with finite mechanical tolerances. Due to practical fabrication limitations, the wafer positioning stage itself does not maintain the wafer in the same orientation throughout its workspace, i.e., the orientation of an axis normal to a top surface of the wafer positioning stage depends on the lateral position of the stage. Similarly, the wafer chuck employed to fix the wafer to the wafer positioning stage is not perfectly flat. In another example, thickness variations across the wafer, the presence of backside particles, or both, give rise to flatness errors, and thus, the orientation of an axis normal to wafer surface under measurement varies depending on location on the wafer surface. In some X-ray based measurement systems the wafer is positioned horizontally, i.e., the surface normal is perpendicular to the direction of the gravitational force. In these examples, an edge gripper makes contact with the wafer at three different locations. This introduces distortion of the wafer surface.

In some x-ray measurement systems, the uncertainty in incidence angle is addressed by iteratively measuring the local angle at each measurement location and adjusting the orientation of the wafer before actual measurements are undertaken. Thus, a set of pre-alignment measurements must be undertaken before collection of the measurement signals employed to estimate values of the parameters of interest. This approach is very slow due to the iteration between measurement of local angle and adjustment of wafer orientation, and the need to perform the iteration at each measurement location on the wafer. Furthermore, a random residual error of approximately 0.1 millidegrees cannot be compensated using this approach. The residual error causes matching issues between measurements performed at different angles and negatively impacts achievable measurement precision. Furthermore, the pre-alignment process for angle of incidence must be performed at each desired azimuth angle at which measurement data is to be collected.

Future metrology and inspection applications present challenges due to increasingly small resolution requirements and the increasingly high value of wafer area. Thus, methods and systems for improved measurements in the presence of wafer distortion are desired.

### SUMMARY

Methods and systems for compensating for uncertainty in illumination angle of incidence to enable accurate measurements of semiconductor structures are described herein. Nominal angles of incidence are the assumed angles of incidence realized by the system when measurement data is collected, e.g., a commanded angle of incidence or an angle of incidence measured by sensors of the wafer positioning system employed to orient the wafer with respect to the illumination beam. However, a nominal angle of incidence does not account for unknown wafer orientation at the measurement location, and thus often does not represent the actual angle of incidence associated with a particular measurement.

As described herein, a user defines the nominal angles of incidence employed during measurement, but the metrology system determines the actual angle of incidence and uses the actual angle of incidence to estimate values of parameters of interest with greater accuracy without having to engage in time consuming pre-alignment activities. By avoiding pre-alignment measurements, move-acquire-move (MAM) times are reduced. Furthermore, accurate estimation of the actual illumination angle of incidence at each measurement over a range of different illumination angles of incidence increases the amount and diversity of measurement signal information available for accurate estimation of parameters of interest. The increased amount of measurement signal information de-correlates various measurement model parameters, leading to more accurate measurement results. This is particularly advantageous when performing measurement of complex structures having a large number of structural features.

In one aspect, a semiconductor measurement system is configured to perform measurements at one or more nominal angles of incidence, estimate the actual angle of incidence corresponding to each measurement, and estimate a value of a parameter of interest characterizing one or more measured structures based at least in part on the collected measurement data and the actual angle of incidence.

In some embodiments, a semiconductor measurement system includes a wafer orientation measurement subsystem employed to measure the actual illumination angle of incidence directly. Furthermore, the measured angle of incidence is provided as input to a measurement model to estimate a value of a parameter of interest characterizing the one or more structures under measurement.

In some other embodiments, a semiconductor measurement system scans the semiconductor wafer over a range of nominal angles of incidence while periodically collecting measurement signals, each set of measurement signals at a different nominal angle of incidence. The actual angle of incidence associated with at least one set of measurement signals is estimated based on a fitting of simulated measurement signals to the actual measurement signals. One or more values of a parameter of interest characterizing a structure under measurement is estimated based on one or more sets measurement signals and the corresponding actual angles of incidence.

In some other embodiments, a semiconductor measurement system includes an illumination subsystem that directs illumination light over a range of angles of incidence simultaneously, and a detector resolves collected radiation by wavelength in one direction and by angle of incidence in another direction orthogonal to the direction of wavelength dispersion. The actual angle of incidence associated with each collected pixel or group of pixels associated with the same AOI is estimated based on a fitting of simulated measurement signals to the actual measurement signals. One or more values of a parameter of interest characterizing a structure under measurement is estimated based on one or more sets measurement signals and the corresponding actual angles of incidence.

In another aspect, a semiconductor measurement system measures the tilt of a feature of one or more structures under measurement by aligning the incident illumination beam with the feature under measurement. In this manner, the actual angle of incidence of a measurement with respect to a tilted structure is accurately estimated, and is available for model based measurements of tilted structures.

In another further aspect, a semiconductor measurement system includes a specimen positioning system configured to rotate a wafer simultaneously about two orthogonal axes aligned with the wafer surface such that the surface of the semiconductor wafer is oriented with respect to the incident illumination beam over a range of azimuth angles at the first nominal angle of incidence. The combined rotations about the two orthogonal axes results in precession motion of the wafer about an axis aligned with the incident illumination beam. The precession motion about the axis aligned with the incident illumination beam exposes the wafer to measurement over a full 360 degree range of azimuth angles at a single angle of incidence. Measurements are collected during the precession motion. At each measurement frame, the detected intensities across the active surface of the detector are summed. The azimuth angle associated with the maximum value of summed intensity is the azimuth angle associated with alignment of the incident illumination beam with the feature under measurement.

In another further aspect, a semiconductor measurement system includes a specimen positioning system configured to rotate a wafer such that the surface of the semiconductor wafer is oriented with respect to the incident illumination beam over a range of angles of incidence at the tilt azimuth angle. Measurements are collected during the rotation motion. At each measurement frame, the detected intensities across the active surface of the detector are summed. The angle of incidence associated with the maximum value of summed intensity is the tilt angle of incidence associated with alignment of the incident illumination beam with the feature under measurement.

In another further aspect, the semiconductor measurement system is further configured to repeat the AOI scan at the tilt azimuth angle over a smaller range of angles of incidence, and a longer integration time to increase the resolution of the AOI measurement.

In another further aspect, one or more sets of measurements and the corresponding actual angle of incidence with respect to a tilted structure are provided as input to a measurement engine to estimate values of one or more parameters of interest characterizing the one or more tilted structures under measurement.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a system for measuring values of one or more parameters of interest characterizing a semiconductor structure after discovery of the actual angle of incidence in accordance with the exemplary methods presented herein.

FIG. 2 is another diagram illustrative of metrology system 100 depicted in FIG. 1.

FIG. 3 is a diagram illustrative of another system for measuring values of one or more parameters of interest characterizing a semiconductor structure after discovery of the actual angle of incidence in accordance with the exemplary methods presented herein.

FIG. 4 depicts an x-ray illumination beam incident on a wafer at a particular orientation described by an angle of incidence, □, and an azimuth angle, □, in one example.

FIG. 5 is a diagram illustrative of a Machine Learning (ML) based measurement engine employing an actual angle of incidence as input in one example.

FIG. 6 is a diagram illustrative of a regression based measurement engine employing an actual angle of incidence as input in one example.

FIG. 7 is a diagram illustrative of an AOI refinement engine employed to determine actual angles of incidence based on measurement signals collected over a range of nominal angles of incidence in one example.

FIG. 8 is a diagram illustrative of an image of detected intensities resolved in wavelength and angle of incidence across a two dimensional surface of a detector.

FIG. 9 is a diagram illustrative of an AOI refinement engine employed to determine actual angles of incidence based on measurement signals collected over a range of nominal angles of incidence in another example.

FIG. 10 is a diagram illustrative of a wafer including a tilted hole feature.

FIG. 11 is a plot illustrative of the normalized sum of measured intensities across all pixels of a detector at each azimuth angle of a T-SAXS measurement of a tilted hole feature.

FIG. 12 is a plot illustrative of the normalized sum of measured intensities across all pixels of a detector at each angle of incidence of a T-SAXS measurement of a tilted hole feature.

FIG. 13 is a flowchart illustrative of a method for determining an actual angle of incidence associated with a measurement performed at a nominal angle of incidence in one example.

FIG. 14 is a flowchart illustrative of a method for estimating a tilt angle associated with a tilted structure fabricated on a wafer in one example.

### DETAILED DESCRIPTION

Reference will now be made in detail to background examples and some embodiments of the invention, examples of which are illustrated in the accompanying drawings.

Methods and systems for compensating for uncertainty in illumination angle of incidence to enable accurate measurements of semiconductor structures are described herein. In some examples, accurate estimates of the actual illumination angle of incidence are derived from external measurement. In some other examples, measurement data collected over a range of nominal illumination angles of incidence are employed to accurately estimate the actual illumination angles of incidence. In some other examples, accurate estimates of the actual illumination angle of incidence with respect to tilted structures are derived from measurement data associated with measurement data collected over a range of nominal illumination angles of incidence.

By avoiding pre-alignment measurements, move-acquire-move (MAM) times are reduced. Furthermore, accurate estimation of the actual illumination angle of incidence at each measurement over a range of different illumination angles of incidence increases the amount and diversity of measurement signal information available for accurate estimation of parameters of interest. The increased amount of measurement signal information de-correlates various measurement model parameters, leading to more accurate measurement results. This is particularly advantageous when performing measurement of complex structures having a large number of structural features.

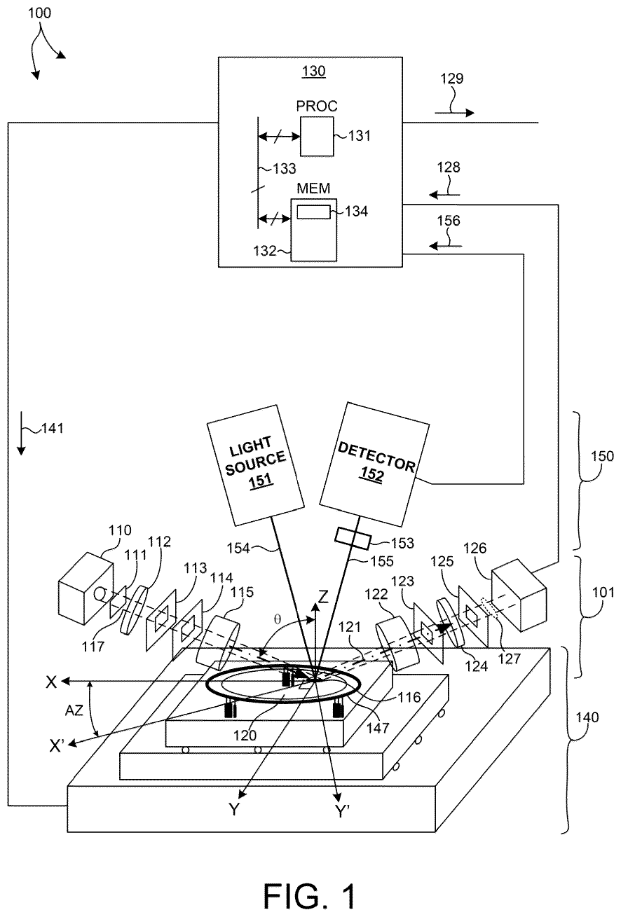

FIG. 1 depicts an exemplary, metrology system 100 for performing measurements of structural features of semiconductor devices. As depicted in FIG. 1, metrology system 100 is configured as a broadband spectroscopic ellipsometer. However, in general, metrology system 100 may be configured as a spectroscopic reflectometer, scatterometer, single wavelength ellipsometer, beam profile reflectometer, or any combination thereof.

Metrology system 100 includes an illumination source 110 that generates a beam of illumination light 117 incident on a wafer 120. In some embodiments, illumination source 110 is a broadband illumination source that emits illumination light in the ultraviolet, visible, and infrared spectra. In one embodiment, illumination source 110 is a laser sustained plasma (LSP) light source (a.k.a., laser driven plasma source). The pump laser of the LSP light source may be continuous wave or pulsed. A laser-driven plasma source can produce significantly more photons than a Xenon lamp across a wavelength range from 150 nanometers to 2000 nanometers. Illumination source 110 can be a single light source or a combination of a plurality of broadband or discrete wavelength light sources. The light generated by illumination source 110 includes a continuous spectrum or parts of a continuous spectrum, from ultraviolet to infrared (e.g., vacuum ultraviolet to mid infrared). In general, illumination light source 110 may include a super continuum laser source, an infrared helium-neon laser source, an arc lamp, or any other suitable light source.

In a further aspect, the amount of illumination light is broadband illumination light that includes a range of wavelengths spanning at least 500 nanometers. In one example, the broadband illumination light includes wavelengths below 250 nanometers and wavelengths above 750 nanometers. In general, the broadband illumination light includes wavelengths between 120 nanometers and 3,000 nanometers. In some embodiments, broadband illumination light including wavelengths beyond 3,000 nanometers may be employed.

As depicted in FIG. 1, metrology system 100 includes an illumination subsystem configured to direct illumination light 117 to one or more structures formed on the wafer 120 at an angle of incidence, □, defined with reference to an axis normal to the surface of wafer 120, e.g., the Z-axis depicted in FIG. 1. The illumination subsystem is shown to include light source 110, one or more optical filters 111, polarizing component 112, field stop 113, pupil aperture stop 114, and illumination optics 115. The one or more optical filters 111 are used to control light level, spectral output, or both, from the illumination subsystem. In some examples, one or more multi-zone filters are employed as optical filters 111. Polarizing component 112 generates the desired polarization state exiting the illumination subsystem. In some embodiments, the polarizing component is a polarizer, a compensator, or both, and may include any suitable commercially available polarizing component. The polarizing component can be fixed, rotatable to different fixed positions, or continuously rotating. Although the illumination subsystem depicted in FIG. 1 includes one polarizing component, the illumination subsystem may include more than one polarizing component. Field stop 113 controls the field of view (FOV) of the illumination subsystem and may include any suitable commercially available field stop. Pupil aperture stop 114 controls the numerical aperture (NA) of the illumination subsystem and may include any suitable commercially available aperture stop. Light from illumination source 110 is directed through illumination optics 115 to be focused on one or more structures (not shown in FIG. 1) on wafer 120. The illumination subsystem may include any type and arrangement of optical filter(s) 111, polarizing component 112, field stop 113, pupil aperture stop 114, and illumination optics 115 known in the art of spectroscopic ellipsometry, reflectometry, and scatterometry.

As depicted, in FIG. 1, the beam of illumination light 117 passes through optical filter(s) 111, polarizing component 112, field stop 113, pupil aperture stop 114, and illumination optics 115 as the beam propagates from the illumination source 110 to wafer 120. Beam 117 illuminates a portion of wafer 120 over a measurement spot 116.

Metrology system 100 also includes a collection optics subsystem configured to collect light generated by the interaction between the one or more structures and the incident illumination beam 117. A beam of collected light 127 is collected from measurement spot 116 by collection optics 122. Collected light 127 passes through pupil aperture stop 123, polarizing element 124, and field stop 125 of the collection optics subsystem.

Collection optics 122 includes any suitable optical elements to collect light from the one or more structures formed on wafer 120. Pupil aperture stop 123 controls the NA of the collection optics subsystem. Polarizing element 124 analyzes the desired polarization state. The polarizing element 124 is a polarizer or a compensator. The polarizing element 124 can be fixed, rotatable to different fixed positions, or continuously rotating. Although the collection subsystem depicted in FIG. 1 includes one polarizing element, the collection subsystem may include more than one polarizing element. Collection field stop 125 controls the field of view of the collection subsystem. The collection subsystem takes light from wafer 120 and directs the light through collection optics 122, and polarizing element 124 to be focused on collection field stop 125. In some embodiments, collection field stop 125 is used as a spectrometer slit for the spectrometers of the detection subsystem. In other embodiments, collection field stop 125 may be located at or near a spectrometer slit of the spectrometers of the detection subsystem.

The collection subsystem may include any type and arrangement of collection optics 122, pupil aperture stop 123, polarizing element 124, and field stop 125 known in the art of spectroscopic ellipsometry, reflectometry, and scatterometry.

In the embodiment depicted in FIG. 1, the collection optics subsystem directs light to spectrometer 126. Spectrometer 126 generates output responsive to light collected from the one or more structures illuminated by the illumination subsystem. In one example, the detectors of spectrometer 126 are charge coupled devices (CCD) sensitive to ultraviolet and visible light (e.g., light having wavelengths between 190 nanometers and 860 nanometers). In other examples, one or more of the detectors of spectrometer 126 is a photo detector array (PDA) sensitive to infrared light (e.g., light having wavelengths between 950 nanometers and 2500 nanometers). However, in general, other detector technologies may be contemplated (e.g., a position sensitive detector (PSD), an infrared detector, a photovoltaic detector, etc.). Each detector converts the incident light into electrical signals indicative of the spectral intensity of the incident light. In general, spectrometer 126 generates output signals 128 indicative of the spectral response of the structure under measurement to the illumination light.

Metrology system 100 also includes computing system 130 configured to receive signals 128 indicative of the measured spectral response of the structure of interest and estimate values 129 of one or more parameters of interest characterizing the one or more structures under measurement, e.g., film thickness, critical dimensions, overlay, etc., based on the measured spectral response.

Wafer stage 140 positions wafer 120 with respect to the ellipsometer subsystem 101. In some embodiments, wafer stage 140 moves wafer 120 in the XY plane by combining two orthogonal, translational movements (e.g., movements in the X and Y directions) to position wafer 120 with respect to the ellipsometer. In some embodiments, wafer stage 140 is configured to control the location of wafer 120 with respect to the illumination provided by the optical ellipsometer in six degrees of freedom. In one embodiment, wafer stage 140 is configured to control the azimuth angle, AZ, of wafer 120 with respect to the illumination provided by the optical ellipsometer by rotation about the z-axis. In general, specimen positioning system 140 may include any suitable combination of mechanical elements to achieve the desired linear and angular positioning performance, including, but not limited to goniometer stages, magnetically levitated stages, hexapod stages, angular stages, and linear stages. Computing system 130 is communicatively coupled to wafer stage 140 and communicates motion command signals 141 to wafer stage 140. In response, wafer stage 140 positions wafer 120 with respect to the ellipsometer in accordance with the motion control commands.

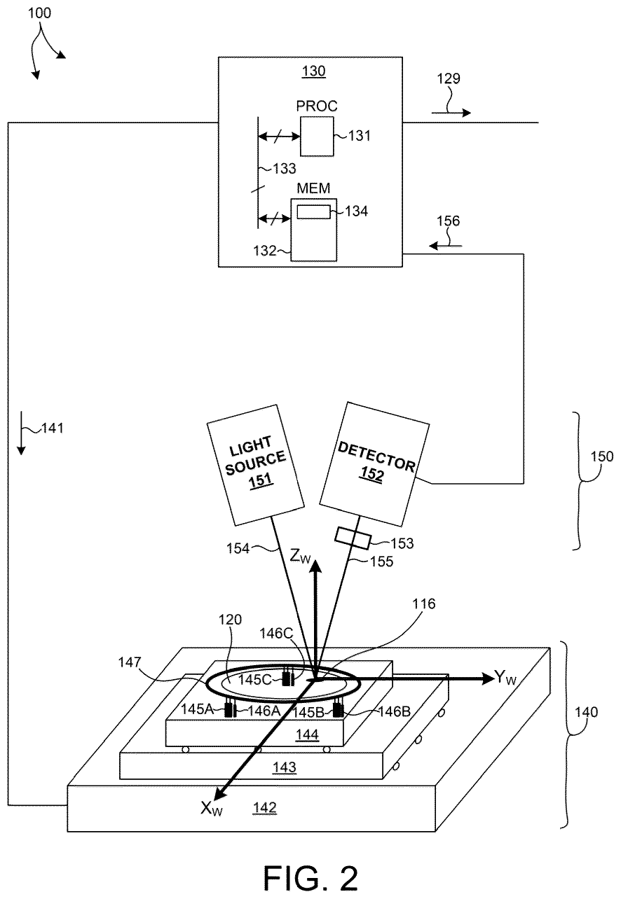

FIG. 2 is another diagram illustrative metrology system 100 depicted in FIG. 1. FIG. 2 does not include the elements of ellipsometer 101 to enable a more visible illustration of wafer stage 140.

As depicted in FIG. 2, wafer coordinate frame {X_{W}, Y_{W}, Z_{W}} is attached to wafer 120. The Z_{W} axis is normal to the surface of wafer 120 at measurement spot 116. The X_{W} and Y_{W} axes are orthogonal to one another and aligned with the surface of wafer 120. Wafer 120 is removably attached to wafer chuck 147, e.g., using a vacuum clamp, electrostatic clamp, edge grip clamp, etc.

As depicted in FIG. 2, wafer stage 140 includes a base frame 142, an X-stage 143, a Y-stage 144, and a three degree of freedom wafer stage supporting wafer chuck 147. In some embodiments, base frame 142 is mechanically coupled to a machine frame to which the measurement subsystem, e.g., ellipsometer 101, is also mechanically coupled. X-stage 143 is mechanically constrained by a bearing assembly, e.g., mechanical, magnetic, or air bearings, to move freely in X_{W} direction with respect to base frame 142. One or more actuators, e.g., linear motors, (not shown) are employed to control the position of X-stage 143 with respect to base frame 142 in the X_{W} direction. Similarly, Y-stage 144 is mechanically constrained by a bearing assembly, e.g., mechanical, magnetic, or air bearings, to move freely in Y_{W} direction with respect to X-stage 143. One or more actuators, e.g., linear motors, (not shown) are employed to control the position of Y-stage 144 with respect to X-stage 143 in the Y_{W} direction. As depicted in FIGS. 1 and 2, Y-stage 144 is stacked on X-stage 143. Together, X-stage 143 and Y-stage 144 provide a long stroke capability, i.e., workspace of at least 300 millimeters in the X_{W} and Y_{W} directions, such that X-stage 143 and Y-stage 144 are controlled to position any location on the surface of wafer 120 under measurement spot 116 defined by the optical elements of ellipsometer 101.

In the embodiment depicted in FIGS. 1 and 2, the three degree of freedom wafer stage includes actuators 145A-C, e.g., voice coil motors, piezoelectric motors, etc.). Each of actuators 145A-C is mechanically coupled between the wafer chuck 147 and Y-stage 144. The direction of extent of each of actuators 145A-C is approximately parallel to the Z_{W} axis, i.e., an axis normal to the surface of the wafer 120, which is clamped to wafer chuck 147. As depicted in FIGS. 1 and 2, actuators 145A-C are spaced apart from one another in the X_{W} and Y_{W} directions. In this configuration, the movements of actuators 145A-C are coordinated to independently control the position of wafer 120 in the Z-direction, the orientation of wafer 120 about the X_{W} axis, and the orientation of wafer 120 about the Y_{W} axis. Movements of wafer 120 specified in {Rₓ, Rₓ, Z} coordinates map to movements of actuators 145A-C by a simple kinematic transformation characterized by the geometric distances between actuators 145A-C and the {X_{W}, Y_{W}, Z_{W}} coordinate frame. In this manner, control commands 141 specifying movements in {Rₓ, Rₓ, Z} coordinates are readily mapped to movements of each actuator. The movements of each actuator are implemented at the actuator level by one or more motion controllers of wafer stage 140.

Similarly, position measurement devices 146A-C, e.g., linear encoders, linear variable differential transformers, inductive probes, capacitive probes, interferometers, etc.) are spaced apart from one another in the X_{W} and Y_{W} directions. In this configuration, the position of wafer 120 with respect to Y-stage 144 in the Z-direction, the orientation of wafer 120 about the X_{W} axis, and the orientation of wafer 120 about the Y_{W} axis are captured by position measurement devices 146A-C. The displacements captured by position measurement devices 146A-C map to displacements of wafer 120 expressed in the {Rₓ, R_{y}, Z} coordinates by a simple kinematic transformation characterized by the geometric distances between position measurement devices 146A-C and the {Rₓ, R_{y}, Z} coordinate frame. In this manner, displacements measured by position measurement devices 146A-C are readily mapped to displacements in {Rₓ, R_{y}, Z} coordinates. The displacements are communicated to computing system 130 for estimation of the actual illumination angle of incidence as described herein. In some embodiments, the displacements are communicated to one or motion controllers of wafer stage 140 to implement a feedback positioning controller that locates wafer 120 at a desired position and orientation based on measurements by position measurement devices 146A-C.

In some embodiments, position measurement devices 146A-C are co-located with actuators 145A-C. Each of the position sensors is located in close proximity to a corresponding actuator, and thus measures a displacement in the direction of extent of each corresponding actuator. However, in general, position measurement devices 146A-C may be located in different locations than actuators 145A-C.

Wafer stage 140 illustrated in FIG. 2 includes a wafer stage having three actuators to generate force in the Z_{W}-direction at three different locations to control three degrees of freedom of wafer 120. However, in general, a wafer stage may include more than three actuators to generate force in the Z_{W} direction at more than three locations to control the three degrees of freedom of wafer 120. Although, such configurations are over-constrained, it may be desirable to include more than three actuators to limit the force requirements on any one actuator, stabilize bending modes in wafer chuck 147, operate in coordination as part of a magnetically levitated wafer chuck 147, etc.

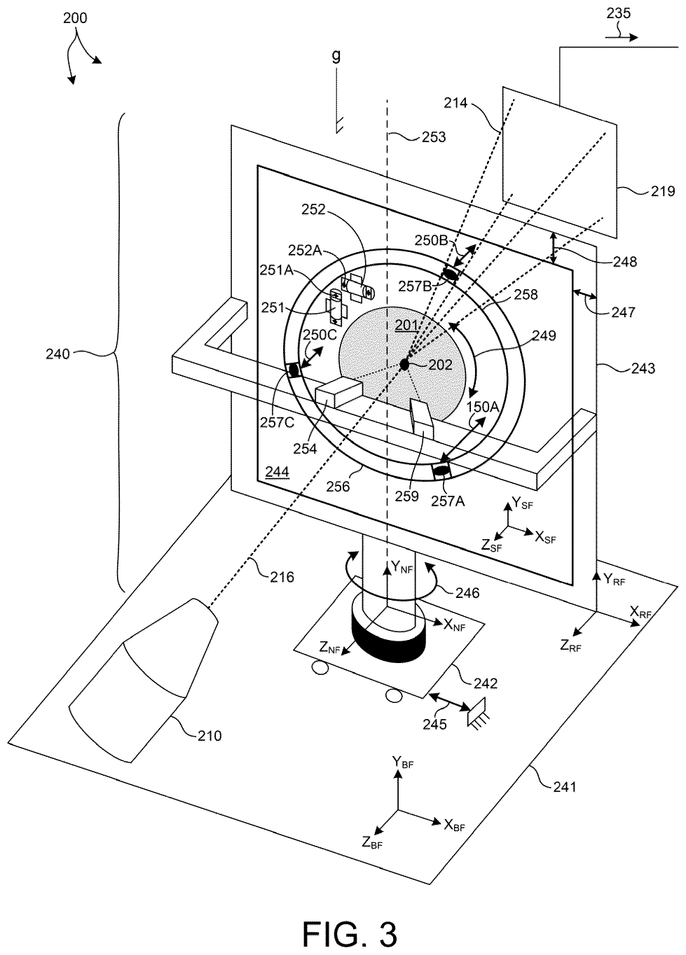

FIG. 3 is diagram illustrative of elements of a Transmission, Small-Angle X-Ray Scatterometry (T-SAXS) measurement system 200 for measuring characteristics of one or more semiconductor structures fabricated on a semiconductor wafer in one embodiment. As shown in FIG. 3, the system 200 may be used to perform T-SAXS measurements over an inspection area 202 of a wafer 201 illuminated by an illumination beam spot.

In the depicted embodiment, system 200 includes an x-ray illumination subsystem 210 including an x-ray illumination source and various elements employed to control the spatial and optical characteristics of the illumination beam 216, e.g., focusing optics, beam divergence control slits, intermediate slits, beam shaping slits, etc. The x-ray illumination source is configured to generate x-ray radiation suitable for T-SAXS measurements. In some embodiments, the x-ray illumination source is configured to generate wavelengths between 0.01 nanometers and 1 nanometer. In general, any suitable high-brightness x-ray illumination source capable of generating high brightness x-rays at flux levels sufficient to enable high-throughput, inline metrology may be contemplated to supply x-ray illumination for T-SAXS measurements. In some embodiments, an x-ray source includes a tunable monochromator that enables the x-ray source to deliver x-ray radiation at different, selectable wavelengths.

In some embodiments, one or more x-ray sources emitting radiation with photon energy greater than 15 keV are employed to ensure that the x-ray source supplies light at wavelengths that allow sufficient transmission through the entire device as well as the wafer substrate. By way of non-limiting example, any of a particle accelerator source, a liquid anode source, a rotating anode source, a stationary, solid anode source, a microfocus source, a microfocus rotating anode source, a plasma based source, and an inverse Compton source may be employed as an x-ray illumination source. In one example, an inverse Compton source available from Lyncean Technologies, Inc., Palo Alto, California (USA) may be contemplated. Inverse Compton sources have an additional advantage of being able to produce x-rays over a range of photon energies, thereby enabling the x-ray source to deliver x-ray radiation at different, selectable wavelengths.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

X-ray detector 219 collects x-ray radiation 214 scattered from wafer 201 and generates an output signals 235 indicative of properties of wafer 201 that are sensitive to the incident x-ray radiation in accordance with a T-SAXS measurement modality. In some embodiments, scattered x-rays 214 are collected by x-ray detector 219 while specimen positioning system 240 locates and orients wafer 201 to produce angularly resolved scattered x-rays.

In some embodiments, a T-SAXS system includes one or more photon counting detectors with high dynamic range (e.g., greater than 10⁵). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 219 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to a computing system via output signals 235 for further processing and storage.

In a further aspect, a T-SAXS system is employed to determine properties of a specimen (e.g., structural parameter values) based on one or more diffraction orders of scattered light. System 200 includes a computing system (not shown), e.g., a computing system analogous to computing system 130 depicted in FIG. 1, employed to acquire signals 235 generated by detector 219 and determine properties of the specimen based at least in part on the acquired signals.

In one aspect, specimen positioning system 240 provides active control of the position of wafer 201 with respect to illumination beam 216 in all six degrees of freedom while supporting wafer 201 vertically with respect to the gravity vector (i.e., the gravity vector is approximately in-plane with the wafer surface and perpendicular to an axis normal to the wafer surface). Specimen positioning system 240 supports wafer 201 at the edges of wafer 201 allowing illumination beam 216 to transmit through wafer 201 over any portion of the active area of wafer 201 without remounting wafer 201.

As depicted in FIG. 3, specimen positioning system 240 includes a base frame 241, a lateral alignment stage 242, a stage reference frame 243, and a wafer stage 244 mounted to stage reference frame 243. For reference purposes, the {X_{BF}, Y_{BF}, Z_{BF}} coordinate frame is attached to base frame 241, the {X_{NF}, Y_{NF}, Z_{NF}} coordinate frame is attached to lateral alignment stage 242, the {X_{RF}, Y_{RF}, Z_{RF}} coordinate frame is attached to stage reference frame 243, and the {X_{SF}, Y_{SF}, Z_{SF}} coordinate frame is attached to wafer stage 244. Wafer 201 is supported on wafer stage 244 by a tip-tilt-Z stage 256 including actuators 250A-C. A rotary stage 258 mounted to tip-tilt-Z stage 256 orients wafer 201 over a range of azimuth angles, □, with respect to illumination beam 216. In the depicted embodiment, three linear actuators 250A-C are mounted to the wafer stage 244 and support rotary stage 258, which, in turn, supports wafer 201.

Actuator 245 translates the lateral alignment stage 242 with respect to the base frame 241 along the X_{BF} axis. Rotary actuator 246 rotates the stage reference frame 243 with respect to lateral alignment stage 242 about an axis of rotation 253 aligned with the Y_{NF} axis. Rotary actuator 246 orients wafer 201 over a range of angles of incidence, □, with respect to illumination beam 216. Wafer stage actuators 247 and 248 translate the wafer stage 244 with respect to the stage reference frame 243 along the X_{RF} and Y_{RF} axes, respectively.

In one aspect, wafer stage 244 is an open aperture, two-axis (XY) linear stacked stage. The open aperture allows the measurement beam to transmit through any portion of the entire wafer (e.g., 300 millimeter wafer). The wafer stage 244 is arranged such that the Y-axis stage extends in a direction approximately parallel to the axis of rotation 253. Furthermore, the Y-axis stage extends in a direction that is approximately aligned with the gravity vector.

Actuators 250A-C operate in coordination to translate the rotary stage 258 and wafer 201 with respect to the wafer stage 244 in the Z_{SF} direction and tip and tilt rotary stage 258 and wafer 201 with respect to the wafer stage 244 about axes coplanar with the X_{SF}-Y_{SF} plane. Rotary stage 258 rotates wafer 201 about an axis normal to the surface of wafer 201. In a further aspect, a frame of rotary stage 258 is coupled to actuators 250A-C by a kinematic mounting system including kinematic mounting elements 257A-C, respectively. In one example, each kinematic mounting element 257A-C includes a sphere attached to a corresponding actuator and a V-shaped slot attached to rotary stage 258. Each sphere makes a two point contact with a corresponding V-shaped slot. Each kinematic mounting element constrains the motion of rotary stage 258 with respect to actuators 250A-C in two degrees of freedom and collectively, the three kinematic mounting elements 257A-C constrain the motion of rotary stage 258 with respect to actuators 250A-C in six degrees of freedom. Each kinematic coupling element is preloaded to ensure that the sphere remains in contact with the corresponding V-shaped slot at all times. In some embodiments, the preload is provided by gravity, a mechanical spring mechanism, or a combination thereof.

In another further aspect, rotary stage 258 is an open aperture, rotary stage. The open aperture allows the measurement beam to transmit through any portion of the entire wafer (e.g., 300 millimeter wafer). The rotary stage 258 is arranged such that its axis of rotation is approximately perpendicular to the axis of rotation 253. Furthermore, the axis of rotation of the rotary stage 258 is approximately perpendicular to the gravity vector. The wafer 201 is secured to the rotary stage 258 via edge grippers to provide full wafer coverage with minimal edge exclusion.

In summary, specimen positioning system 240 is capable of actively controlling the position of wafer 201 in six degrees of freedom with respect to the illumination beam 216 such that illumination beam 216 may be incident at any location on the surface of wafer 201 (i.e., at least 300 millimeter range in X_{RF} and Y_{RF} directions). Rotary actuator 246 is capable of rotating the stage reference frame 243 with respect to the illumination beam 216 such that illumination beam 216 may be incident at the surface of wafer 201 at any of a large range of angles of incidence (e.g., greater than two degrees). In one embodiment, rotary actuator 246 is configured to rotate stage reference frame 243 over a range of at least sixty degrees. Rotary actuator 258 mounted to wafer stage 244 is capable of rotating the wafer 201 with respect to the illumination beam 216 such that illumination beam 216 may be incident at the surface of wafer 201 at any of a large range of azimuth angles (e.g., at least ninety degrees rotational range). In some embodiments, the range of azimuth angles is at least one hundred ninety degrees rotational range. In some embodiments, the range of azimuth angles is a full rotation of wafer 201, i.e., 360 degrees.

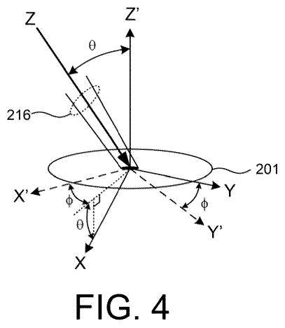

In general, each orientation of an illumination beam relative to the surface normal of a semiconductor wafer is described by any two angular rotations of wafer with respect to the illumination beam, or vice-versa. In one example, the orientation can be described with respect to a coordinate system fixed to the wafer. FIG. 4 depicts x-ray illumination beam 216 incident on wafer 201 at a particular orientation described by an angle of incidence, □, and an azimuth angle, □. Coordinate frame XYZ is fixed to the metrology system (e.g., illumination beam 216) and coordinate frame X′Y′Z′ is fixed to wafer 201. The Y axis is aligned in plane with the surface of wafer 201. X and Z are not aligned with the surface of wafer 201. Z′ is aligned with an axis normal to the surface of wafer 201, and X′ and Y′ are in a plane aligned with the surface of wafer 201. As depicted in FIG. 4, x-ray illumination beam 216 is aligned with the Z-axis and thus lies within the XZ plane. Angle of incidence, □, describes the orientation of the x-ray illumination beam 216 with respect to the surface normal of the wafer in the XZ plane. Furthermore, azimuth angle, □, describes the orientation of the XZ plane with respect to the X′Z′ plane. Together, □ and □□ uniquely define the orientation of the x-ray illumination beam 216 with respect to the surface of wafer 201. In this example, the orientation of the x-ray illumination beam 216 with respect to the surface of wafer 201 is described by a rotation about an axis normal to the surface of wafer 201 (i.e., Z′ axis) and a rotation about an axis aligned with the surface of wafer 201 (i.e., Y axis). In some other examples, the orientation of the x-ray illumination beam 216 with respect to the surface of wafer 201 is described by a rotation about a first axis aligned with the surface of wafer 201 and another axis aligned with the surface of wafer 201 and perpendicular to the first axis.

In some embodiments, both metrology systems 100 and 200 include a specimen positioning system configured to actively position a wafer in six degrees of freedom with respect to the illumination beam, including a range of angles of incidence and azimuth angles, as depicted in FIG. 4. In one example, computing system 130 communicates command signals 141 to specimen positioning system 140 that indicate the desired position of wafer 120. In response, specimen positioning system 140 generates command signals to the various actuators of specimen positioning system 140 to achieve the desired positioning of wafer 120.

In one aspect, a semiconductor measurement system, such as systems 100 and 200 described herein, is configured to perform measurements at one or more nominal angles of incidence, estimate the actual angle of incidence corresponding to each measurement, and estimate a value of a parameter of interest characterizing one or more measured structures based at least in part on the collected measurement data and the actual angle of incidence. The nominal angles of incidence are the assumed angles of incidence realized by the system when measurement data is collected, e.g., a commanded angle of incidence or an angle of incidence measured by sensors of the wafer positioning system employed to orient the wafer with respect to the illumination beam.

In this manner, a user defines the nominal angles of incidence employed during measurement, but the metrology system determines the actual angle of incidence and uses the actual angle of incidence to estimate values of parameters of interest with greater accuracy without having to engage in time consuming pre-alignment activities.

In some embodiments, a semiconductor measurement system includes a wafer orientation measurement subsystem employed to measure the actual illumination angle of incidence directly.

In the embodiment depicted in FIGS. 1 and 2, metrology system 100 also includes a wafer orientation measurement subsystem 150 coupled to the same machine frame as the measurement subsystem, e.g., ellipsometer 101. As depicted in FIGS. 1 and 2, wafer orientation measurement subsystem includes an optical illumination source 151 configured to generate an optical illumination beam 154 directed to the surface of wafer 120 at measurement spot 116. Light 155 reflected from the surface of wafer 120 in response to optical illumination beam 154 is focused by focusing optics 153 onto optical detector 152. Optical detector 152 generates signals 156 indicative of the orientation of wafer 120 with respect to the measurement subsystem, e.g., ellipsometer 101, at measurement spot 116 on the surface of wafer 120 based on a location of incidence of light 155 on optical detector 152. The measured orientation is the in-plane orientation of wafer 120, e.g., an orientation expressed in terms of angular position about the X_{W} and Y_{W} axes, which, by definition, lie within the same plane as the surface of the wafer. Rotational displacement about the Z_{W} axis is not captured by wafer orientation measurement subsystem 150.

In some embodiments, optical illumination source 151 is a Light Emitting Diode (LED) based light source. In other embodiments, optical illumination source 151 is a laser based light source. In some embodiments, optical illumination source is a Xenon arc-lamp based light source. In some of these embodiments, the optical illumination source is the same illumination source employed by the measurement subsystem, e.g., illumination source 110 of ellipsometer 101. In some embodiments, optical detector 152 is a quadrant cell photoreceiver. However, in general, any suitable optical illumination source and optical detector may be employed to measure the in-plane orientation of wafer 120 with respect to the measurement system at measurement spot 116 on the surface of wafer 120.

The measurement of in-plane orientation of wafer 120 using an optical detector, such as a quadrant cell photoreceiver is sensitive to structures fabricated on the surface of wafer 120, in particular high aspect ratio structures and thick films.

In the embodiment depicted in FIG. 3, T-SAXS system 200 also includes a wafer orientation measurement subsystem coupled to the same machine frame as the measurement subsystem. The wafer orientation measurement system operates in accordance with the description provided with reference to wafer orientation measurement subsystem 150 depicted in FIGS. 1 and 2. In the diagram illustrated in FIG. 3, optical illumination source 254 is analogous to optical illumination source 151 depicted in FIGS. 1 and 2, and optical detector 259 is analogous to optical detector 152 depicted in FIGS. 1 and 2.

In another further aspect, the measured angle of incidence is provided as input to a measurement model to estimate a value of a parameter of interest characterizing the one or more structures under measurement.

In some examples, the measurement model is a machine learning based model, and the measured angle of incidence associated with each measurement is treated as the actual value of the angle of incidence provided as a conditional input to the machine learning based model.

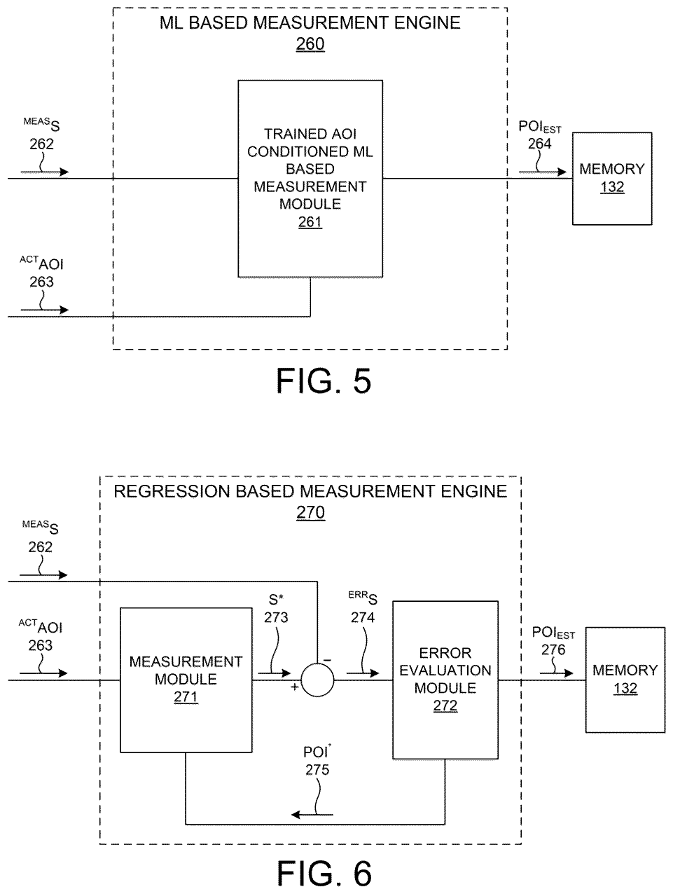

FIG. 5 is a diagram illustrative of a Machine Learning (ML) based measurement engine 260 implemented by a computing system associated with one or more metrology systems, such as computing system 130 depicted in FIG. 1. As depicted in FIG. 5, ML based measurement engine 260 includes a trained AOI conditioned ML based measurement module 261. AOI conditioned ML based measurement module 261 includes an ML based measurement model trained with the actual angle of incidence provided as a conditional input to the ML model. As depicted in FIG. 5, AOI conditioned ML based measurement module 261 receives a sets of measurement signals, ^{MEAS}S 262, associated with the measurement of a structure of interest at a nominal angle of incidence as input. Moreover, AOI conditioned ML based measurement module 261 receives the actual value of the angle of incidence, ^{ACT}AOI 263, associated with the set of measurement signals, ^{MEAS}S 262, as a conditional input to the AOI conditioned ML based measurement model. The AOI conditioned ML based measurement model generates an estimated value of a parameter of interest, POI_{EST} 264, based on measurement signals, ^{MEAS}S 262, provided as input, and corresponding actual value of the angle of incidence, ^{ACT}AOI 263, provided as conditional input. The Machine Learning (ML) based measurement engine 260 communicates estimated values of parameters of interest, POI_{EST} 263, to a memory, e.g., memory 132.

In some other examples, the measurement model is a physics based model, and the measured angle of incidence associated with each measurement is treated as the actual value of the angle of incidence provided as an input to the physics based model.

FIG. 6 is a diagram illustrative of a regression based measurement engine 270 implemented by a computing system associated with one or more metrology systems, such as computing system 130 depicted in FIG. 1. As depicted in FIG. 6, regression based measurement engine 270 includes a measurement module 271 and error evaluation module 272.

As depicted in FIG. 6, regression based measurement engine 270 receives a set of measurement signals, ^{MEAS}S 262, and the actual value of the angle of incidence, ^{ACT}AOI 263, corresponding to the set of measurement signals, ^{MEAS}S 262. Measurement module 271 includes a physics based measurement model that simulates measurement signals, S* 273, generated by the measurement system at the current value of one or more parameters of interest and a set of values of many measurement system parameters, including the actual angle of incidence, ^{ACT}AOI 263.

Regression based measurement engine 270 computes the difference between the simulated measurement signal values, S* 273, and the measurement signal values, ^{MEAS}S 262 to generate an error associated with each of the measurement signal values, ^{ERR}S 274. Error evaluation module 272 generates updated values of the parameters of interest, POI* 275, based on the errors. The updated values of the parameters of interest, POI* 275, are communicated to measurement module 271. The updated measurement model again generates estimated measurement signal values, S* 273, based on the measurement model evaluated at the current values of the parameters of interest, POI* 275 and the actual angle of incidence, ^{ACT}AOI 263. Regression based measurement engine 270 iterates until an exit criteria is reached, e.g., a measure of the magnitude of the measurement signal errors fall below a predetermined threshold value, a maximum number of iterations in reached, changes in values of the parameters of interest fall below a predetermined threshold value, etc. When the exit criteria are reached, the regression based measurement engine 270 communicates the estimated values of the parameters of interest, POI_{EST} 276, to a memory, e.g., memory 132.

By way of non-limiting example, the measurement signals described with reference to FIGS. 5 and 6 may be generated by metrology system 100, i.e., measured spectra, metrology system 200, i.e., measured diffraction images, or any other measurement system employing an illumination beam incident on a semiconductor wafer.

In another further aspect, a semiconductor measurement system scans the semiconductor wafer over a range of nominal angles of incidence while periodically collecting measurement signals, each set of measurement signals at a different nominal angle of incidence. The actual angle of incidence associated with at least one set of measurement signals is estimated based on a fitting of simulated measurement signals to the actual measurement signals. One or more values of a parameter of interest characterizing a structure under measurement are estimated based on one or more sets measurement signals and the corresponding actual angles of incidence.

In one embodiment, specimen positioning system 240 depicted in FIG. 3 is commanded to scan over a range of nominal angle of incidence, e.g., 10 degrees/second, while capturing images in a burst mode, e.g., 50 Hz image capture rate, in response to a hardware trigger synchronized with the scan rate. In this manner, measurement system 200 collects a number of images, each at a different nominal angle of incidence.

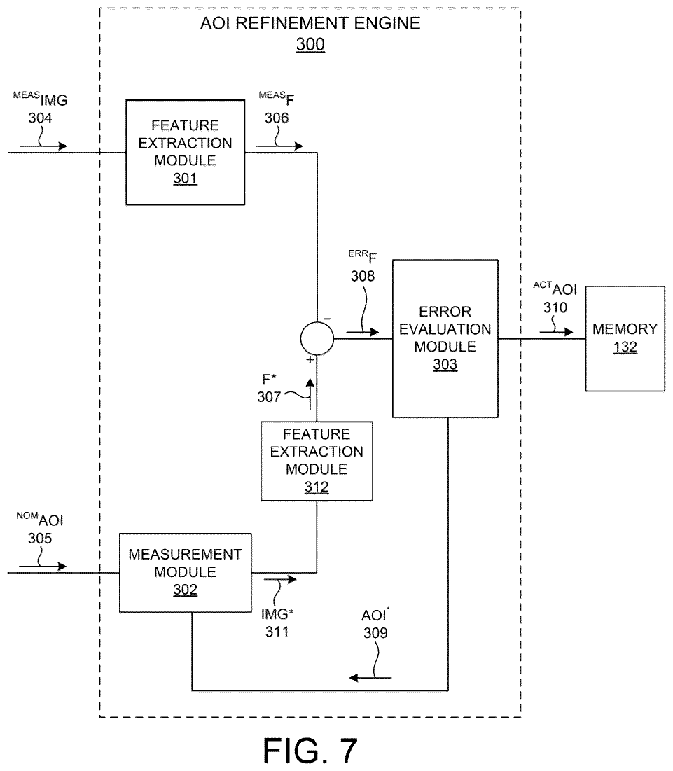

FIG. 7 is a diagram illustrative of an AOI refinement engine 300 implemented by a computing system associated with one or more metrology systems, such as metrology system 200 depicted in FIG. 3. As depicted in FIG. 7, AOI refinement engine 300 includes feature extraction modules 301 and 312, a measurement module 302, and error evaluation module 303.

As depicted in FIG. 7, AOI refinement engine 300 receives a set of measurement signals, ^{MEAS}IMG 304, and the corresponding nominal value of the angle of incidence, ^{NOM}AOI 305, associated with the set of measurement signals. In one example, each set of measurement signals, ^{MEAS}IMG 304, is an image collected from the scan over the range of nominal angles of incidence by measurement system 200 described hereinbefore. Feature extraction module 301 includes an image processing model that captures one or more features, ^{MEAS}F 306, of the measured image, ^{MEAS}IMG 304. By way of non-limiting example, a feature is a diffraction order location on the collected image that is indicative of the actual angle of incidence associated with that particular measurement event. In general, any feature indicative of the actual angle of incidence associated with the captured image may be contemplated within the scope of this patent document.

Measurement module 302 includes a measurement model that simulates the image, IMG* 311, generated by the measurement system at the nominal angle of incidence, ^{NOM}AOI 305. Feature extraction module 312 includes the same image processing model as feature extraction module 301, and captures one or more features, F* 307, of the simulated image, IMG* 311. AOI refinement engine 300 computes the difference between the simulated features, F* 307, and the measured features, ^{MEAS}F 306 to generate an error associated with each feature, ^{ERR}F 308. Error evaluation module 303 generates updated values of the angle of incidence, AOI* 309, based on the errors. The updated value of the angle of incidence is communicated to measurement module 302. The updated measurement model again generates a simulated image, IMG* 311, based on the measurement model evaluated at the current value of the angle of incidence, AOI* 309. AOI refinement engine 300 iterates until an exit criteria is reached, e.g., a measure of the magnitude of the errors fall below a predetermined threshold value, a maximum number of iterations in reached, changes in value of the angle of incidence falls below a predetermined threshold value, etc. When the exit criteria are reached, the AOI refinement engine 300 communicates the actual value of the angle of incidence, ^{ACT}AOI 310, to a memory, e.g., memory 132.

In a further aspect, one or more of the measured images, ^{MEAS}IMG 304, and corresponding actual angles of incidence, ^{ACT}AOI 310, are provided as input to ML based measurement engine 260 or regression based measurement engine 270 to estimate values of one or more parameters of interest characterizing the one or more structures under measurement.

In general, the measurement signals described with reference to FIG. 7 may be generated by metrology system 100, i.e., measured spectra, metrology system 200, i.e., measured diffraction images, or any other measurement system employing an illumination beam incident on a semiconductor wafer.

In another further aspect, a semiconductor measurement system includes an illumination subsystem that directs illumination light over a range of angles of incidence simultaneously, and a detector having an active surface that extends in two directions, such that the detector resolves collected radiation by wavelength in one direction and by angle of incidence in another direction orthogonal to the direction of wavelength dispersion. The actual angle of incidence associated with each collected pixel or group of pixels associated with the same AOI is estimated based on a fitting of simulated measurement signals to the actual measurement signals. One or more values of a parameter of interest characterizing a structure under measurement is estimated based on one or more sets measurement signals and the corresponding actual angles of incidence.

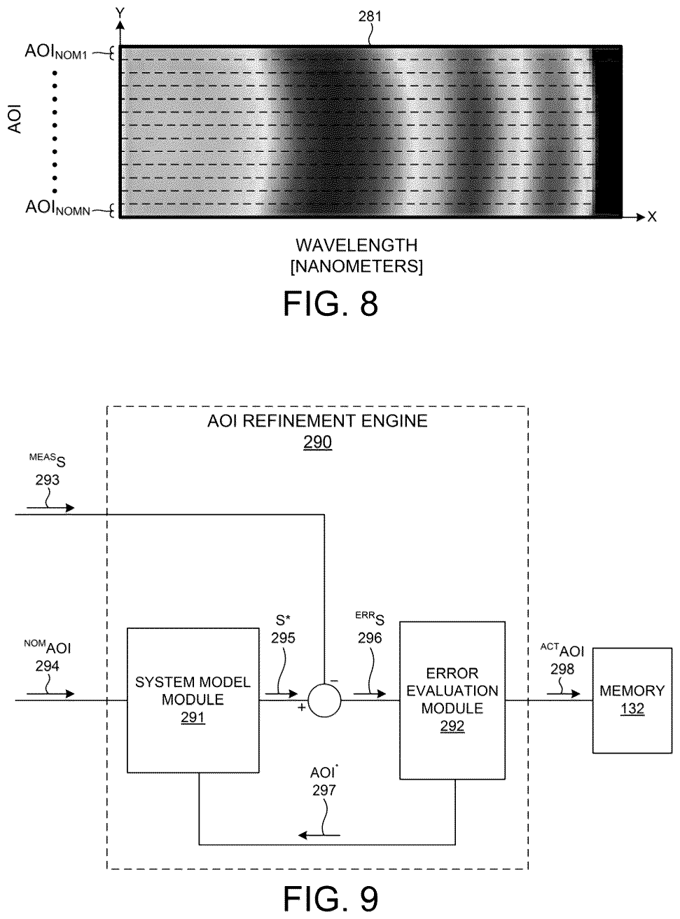

In some embodiments, pupil aperture stop 114 of metrology system 100 depicted in FIGS. 1 and 2, transmits illumination light over a range of nominal angles of incidence simultaneously. In some embodiments, the illumination numerical aperture is at least 0.1. In addition, spectrometer 126 includes a dispersive element that disperses collected radiation 127 in two dimensions across the active surface of a detector of spectrometer 126. FIG. 8 is a diagram illustrative of an image 281 of detected intensities across a two dimensional surface of a detector of spectrometer 126. As depicted in FIG. 8, spectrometer 126 disperses collected light in X-direction according to wavelength and in the Y-direction according to AOI. As depicted in FIG. 8, the X and Y directions are orthogonal to one another. As depicted in FIG. 8, the detector of spectrometer 126 includes N rows of pixels (sets of pixels aligned in the X-direction). Each row of pixels captures the spectral intensity of collected measurement signals associated with the same nominal angle of incidence, e.g., AOI_{NOM1} . . . AOI_{NOMN}.

FIG. 9 is a diagram illustrative of an AOI refinement engine 290 implemented by a computing system associated with one or more metrology systems, such as metrology system 100 depicted in FIGS. 1 and 2. As depicted in FIG. 9, AOI refinement engine 290 includes a system model module 291 and error evaluation module 292.

As depicted in FIG. 9, AOI refinement engine 290 receives a set of measurement signals, ^{MEAS}S 293, and the corresponding nominal value of the angle of incidence, ^{NOM}AOI 294, associated with a set of measurement signals associated with the same nominal value of the angle of incidence. In one example, a set of measurement signals includes one row of measured intensities associated with the same nominal angle of incidence as depicted in FIG. 8. In another example, a set of measurement signals includes one pixel of measured intensities associated with a nominal angle of incidence as depicted in FIG. 8. Thus, in the embodiment depicted in FIG. 8, the actual angle of incidence could be evaluated pixel by pixel or pixel row by pixel row.

System model module 291 includes a measurement model that simulates the spectral intensities, S* 295, generated by the measurement system at the nominal angle of incidence, ^{NOM}AOI 294. AOI refinement engine 290 computes the difference between the simulated spectral intensities, S* 295, and the measured spectral intensities, ^{MEAS}S 293 to generate an error associated with each pixel or row of pixels, ^{ERR}S 296. Error evaluation module 292 generates updated values of the angle of incidence, AOI* 297, based on the errors. The updated value of the angle of incidence is communicated to system model module 291. The updated measurement model again generates simulated spectral intensities, S* 295, based on the measurement model evaluated at the current value of the angle of incidence, AOI* 297. AOI refinement engine 290 iterates until an exit criteria is reached, e.g., a measure of the magnitude of the errors fall below a predetermined threshold value, a maximum number of iterations in reached, changes in value of the angle of incidence falls below a predetermined threshold value, etc. When the exit criteria are reached, the AOI refinement engine 290 communicates the actual value of the angle of incidence, ^{ACT}AOI 298, to a memory, e.g., memory 132.

In a further aspect, one or more sets of spectral measurements, ^{MEAS}S 293, and corresponding actual angle of incidence, ^{ACT}AOI 298, are provided as input to ML based measurement engine 260 or regression based measurement engine 270 to estimate values of one or more parameters of interest characterizing the one or more structures under measurement.

In another further aspect, a semiconductor measurement system measures the tilt of a feature of one or more structures under measurement by aligning the incident illumination beam with the feature under measurement. In this manner, the actual angle of incidence of a measurement with respect to a tilted structure is accurately estimated, and is available for model based measurements of tilted structures.

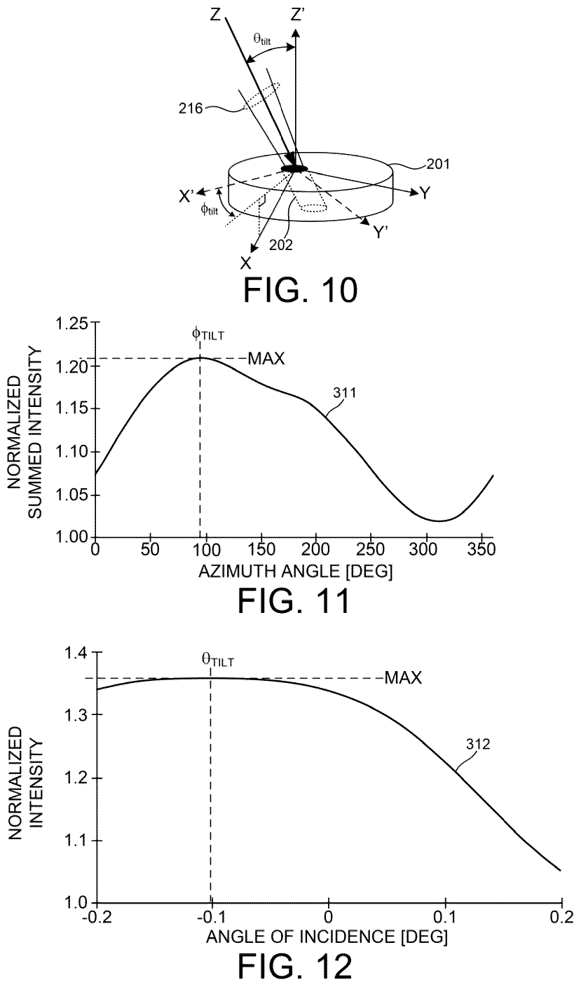

FIG. 10 is a diagram illustrative of wafer 201 including a tilted hole feature 202. As depicted in FIG. 10, hole feature 202 is not aligned with a normal to the surface of wafer 201, e.g., the Z′ axis. Rather, the hole feature is oriented with respect to the wafer surface normal by an angle of incidence, □ₜᵢₗₜ, and azimuth angle, □ₜᵢₗₜ. For a transmission based measurement system, e.g., T-SAXS measurement system 200 depicted in FIG. 3, the illumination beam, e.g., illumination beam 216, is aligned with tilted hole feature 202 when the detected optical signal is maximal, i.e., the maximal number of photons pass through the hole feature. For a reflection based measurement system, e.g., a spectroscopic reflectometry system, the illumination beam is aligned with tilted hole feature when the detected optical signal is maximal, i.e., the maximal number of photons reach the bottom of the structure, reflect from the bottom, and reach the detector.

In a further aspect, a semiconductor measurement system includes a specimen positioning system configured to rotate a wafer simultaneously about two orthogonal axes aligned with the wafer surface such that the surface of the semiconductor wafer is oriented with respect to the incident illumination beam over a range of azimuth angles at the first nominal angle of incidence. The combined rotations about the two orthogonal axes results in precession motion of the wafer about an axis aligned with the incident illumination beam, e.g., the Z axis depicted in FIG. 10. The precession motion about the axis aligned with the incident illumination beam exposes the wafer to measurement over a full 360 degree range of azimuth angles at a single angle of incidence. Measurements are collected during the precession motion. At each measurement frame, the detected intensities across the active surface of the detector are summed. The azimuth angle associated with the maximum value of summed intensity is the azimuth angle associated with alignment of the incident illumination beam with the feature under measurement.

FIG. 11 is a plot illustrative of a plotline 311 of the normalized sum of the measured intensities across all pixels of the detector at each azimuth angle for a T-SAXS measurement of wafer 201 depicted in FIG. 10 by T-SAXS measurement system depicted in FIG. 3. As illustrated in FIG. 11, the azimuth angle at the maximum value of plotline 311 is selected as the tilt azimuth angle, □ₜᵢₗₜ, at which the incident illumination beam 216 is aligned with hole feature 202.

In another further aspect, a semiconductor measurement system includes a specimen positioning system configured to rotate a wafer about a single axis aligned with the wafer surface such that the surface of the semiconductor wafer is oriented with respect to the incident illumination beam over a range of angles of incidence at the tilt azimuth angle. Measurements are collected during the rotation motion. At each measurement frame, the detected intensities across the active surface of the detector are summed. The angle of incidence associated with the maximum value of summed intensity is the tilt angle of incidence associated with alignment of the incident illumination beam with the feature under measurement.

FIG. 12 is a plot illustrative of a plotline 312 of the normalized sum of the measured intensities across all pixels of the detector at each angle of incidence for a T-SAXS measurement of wafer 201 depicted in FIG. 10 by T-SAXS measurement system depicted in FIG. 3 during rotation of the semiconductor wafer with respect to the incident illumination beam over a range of angles of incidence at the tilt azimuth angle, □ₜᵢₗₜ. As illustrated in FIG. 12, the angle of incidence at the maximum value of plotline 312 is selected as the tilt angle of incidence, □ₜᵢₗₜ, at which the incident illumination beam 216 is aligned with hole feature 202.

In another further aspect, the semiconductor measurement system is further configured to repeat the AOI scan at the tilt azimuth angle over a smaller range of angles of incidence, and a longer integration time to increase the resolution of the AOI measurement. Again, the semiconductor measurement system rotates the wafer about the single axis aligned with the wafer surface such that the surface of the semiconductor wafer is oriented with respect to the incident illumination beam over a smaller range of angles of incidence at the tilt azimuth angle compared to the initial AOI scan. The range of the subsequent AOI scan is typically centered about the initial estimate of the tilt angle of incidence, □ₜᵢₗₜ. Measurements are collected during the rotation motion with longer integration time. At each measurement frame, the detected intensities across the active surface of the detector are summed. The angle of incidence associated with the maximum value of summed intensity during the subsequent measurement sequence is a refined tilt angle of incidence associated with alignment of the incident illumination beam with the feature under measurement.

In a further aspect, one or more sets of measurements and the corresponding actual angle of incidence with respect to a tilted structure are provided as input to a measurement engine, e.g., ML based measurement engine 260, regression based measurement engine 270, etc., to estimate values of one or more parameters of interest characterizing the one or more tilted structures under measurement.

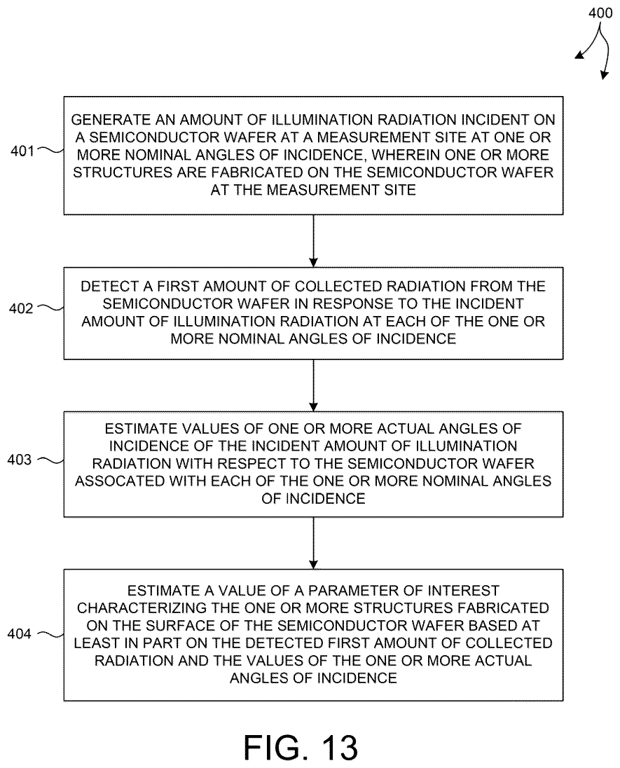

FIG. 13 illustrates a method 400 suitable for implementation by a metrology system such as metrology system 100 illustrated in FIGS. 1 and 2 and metrology system 200 illustrated in FIG. 3 of the present invention. In one aspect, it is recognized that data processing blocks of method 400 may be carried out via a pre-programmed algorithm executed by one or more processors of computing system 130, or any other general purpose computing system. It is recognized herein that the particular structural aspects of metrology systems 100 and 200 do not represent limitations and should be interpreted as illustrative only.

In block 401, an amount of illumination radiation is generated and is incident on a semiconductor wafer at a measurement site at one or more nominal angles of incidence. One or more structures are fabricated on the semiconductor wafer at the measurement site.

In block 402, a first amount radiation collected from the semiconductor wafer in response to the incident amount of illumination radiation is detected at each of the one or more nominal angles of incidence.

In block 403, values of one or more actual angles of incidence of the incident amount of illumination radiation with respect to the semiconductor wafer are estimated. The one or more actual angles of incidence are associated with each of the one or more nominal angles of incidence.

In block 404, a value of a parameter of interest characterizing the one or more structures fabricated on the surface of the semiconductor wafer is estimated based at least in part on the detected first amount of collected radiation and the values of the one or more actual angles of incidence.

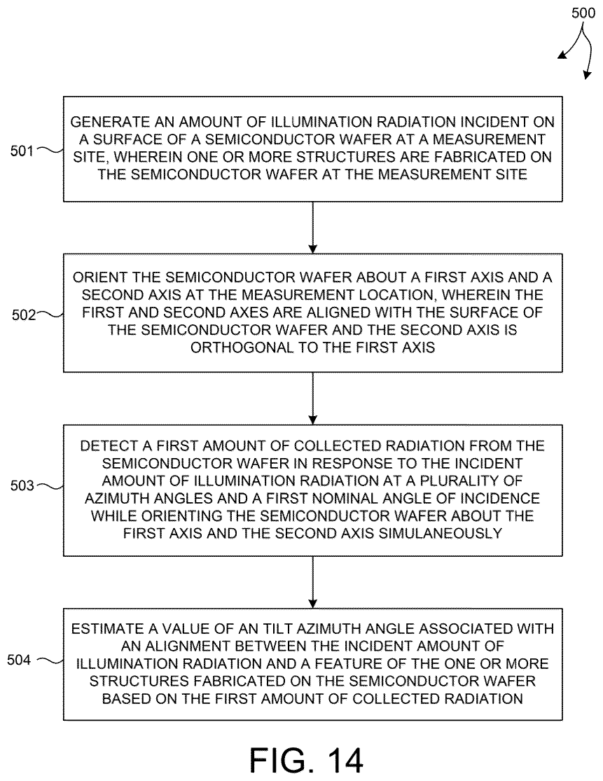

FIG. 14 illustrates a method 500 suitable for implementation by a metrology system such as metrology system 100 illustrated in FIGS. 1 and 2 and metrology system 200 illustrated in FIG. 3 of the present invention. In one aspect, it is recognized that data processing blocks of method 500 may be carried out via a pre-programmed algorithm executed by one or more processors of computing system 130, or any other general purpose computing system. It is recognized herein that the particular structural aspects of metrology systems 100 and 200 do not represent limitations and should be interpreted as illustrative only.

In block 501, an amount of illumination radiation is generated and is incident on a surface of a semiconductor wafer at a measurement site. One or more structures are fabricated on the semiconductor wafer at the measurement site.

In block 502, the semiconductor wafer is oriented about a first axis and a second axis at the measurement location. The first and second axes are aligned with the surface of the semiconductor wafer and the second axis is orthogonal to the first axis.

In block 503, a first amount of radiation collected from the semiconductor wafer in response to the incident amount of illumination radiation is detected at a plurality of azimuth angles and a first nominal angle of incidence while orienting the semiconductor wafer about the first axis and the second axis simultaneously.

In block 504, a value of a tilt azimuth angle associated with an alignment between the incident amount of illumination radiation and a feature of the one or more structures fabricated on the semiconductor wafer is estimated based on the first amount of collected radiation.

Exemplary measurement techniques that may benefit from compensating for the uncertainty of angle of incidence during measurement described herein include, but are not limited to, optical spectroscopic tools such as a Mueller ellipsometer, spectroscopic ellipsometer, single wavelength ellipsometer, spectroscopic reflectometer, beam profile reflectometer, an imaging reflectometer, an imaging spectroscopic reflectometer, a polarized spectroscopic imaging reflectometer, a scanning reflectometer system, a system with two or more reflectometers capable of parallel data acquisition, a system with two or more spectroscopic reflectometers capable of parallel data acquisition, a system with two or more polarized spectroscopic reflectometers capable of parallel data acquisition, a system with two or more polarized spectroscopic reflectometers capable of serial data acquisition without moving the wafer stage or moving any optical elements or the reflectometer stage, imaging spectrometers, imaging system with wavelength filter, imaging system with long-pass wavelength filter, imaging system with short-pass wavelength filter, imaging system without wavelength filter, interferometric imaging system, imaging ellipsometer, imaging spectroscopic ellipsometer, a scanning ellipsometer system, a system with two or more ellipsometers capable of parallel data acquisition, a system with two or more ellipsometers capable of serial data acquisition without moving the wafer stage or moving any optical elements or the ellipsometer stage, a Michelson interferometer, a Mach-Zehnder interferometer, a Sagnac interferometer, a scanning angle of incidence system, a scanning azimuth angle system, a wafer inspection system, an x-ray based metrology system, and electron beam metrology tool, etc. Furthermore, in general, measurement data collected by different measurement technologies and analyzed in accordance with the methods described herein may be collected from multiple tools, rather than one tool integrating multiple technologies.

In a further embodiment, systems 100 and 200 may include one or more computing systems, e.g. computing system 130, employed to perform measurements in accordance with the methods described herein. In one example, the one or more computing systems 130 may be communicatively coupled to the detectors 126 and 152. In one aspect, the one or more computing systems 130 are configured to receive measurement data 128 associated with measurements of metrology targets disposed on specimen 120.

It should be recognized that the various steps described throughout the present disclosure may be carried out by a single computer system 130 or, alternatively, a multiple computer system 130. Moreover, different subsystems of the system 100, such as detectors 126 and 152, wafer stage 140, etc., may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

In addition, the computer system 130 may be communicatively coupled to detectors 126 and 152 in any manner known in the art. For example, the one or more computing systems 130 may be coupled to computing systems associated with detectors 126 and 152. In another example, detectors 126 and 152 may be controlled directly by a single computer system coupled to computer system 130.

The computer system 130 of metrology system 100 may be configured to receive and/or acquire data or information from the subsystems of the system (e.g., detectors 126, 152, and the like) by a transmission medium that may include wireline and/or wireless portions. In this manner, the transmission medium may serve as a data link between the computer system 130 and other subsystems of the system 100.

Computer system 130 of metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, a reference measurement source, or other external systems). For example, the computing system 130 may be configured to receive measurement data from a storage medium (i.e., memory 132 or an external memory) via a data link. For instance, measurement results obtained using detectors 126 and 152 may be stored in a permanent or semi-permanent memory device (e.g., memory 132 or an external memory). In this regard, the measurement results may be imported from on-board memory or from an external memory system. Moreover, the computer system 130 may send data to other systems via a transmission medium. For instance, a measurement model or estimated values of one or more parameters of interest 129 determined by computer system 130 may be communicated and stored in an external memory. In this regard, measurement results may be exported to another system.

Computing system 130 may include, but is not limited to, a personal computer system, cloud-based computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIGS. 1 and 2, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In another further aspect, a metrology system employed to perform measurements as described herein (e.g., metrology system 100) includes an infrared optical measurement system. In these embodiments, the metrology system 100 includes an infrared light source (e.g., an arc lamp, an electrode-less lamp, a laser sustained plasma (LSP) source, or a supercontinuum source). An infrared supercontinuum laser source is preferred over a traditional lamp source because of the higher achievable power and brightness in the infrared region of the light spectrum. In some examples, the power provided by the supercontinuum laser enables measurements of overlay structures with opaque film layers.

A potential problem in overlay measurement is insufficient light penetration to the bottom grating. In many examples, there are non-transparent (i.e., opaque) film layers between the top and the bottom gratings. Examples of such opaque film layers include amorphous carbon, tungsten silicide (WSIₓ), tungsten, titanium nitride, amorphous silicon, and other metal and non-metal layers. Often, illumination light limited to wavelengths in the visible range and below (e.g., between 250 nm and 700 nm) does not penetrate to the bottom grating. However, illumination light in the infrared spectrum and above (e.g., greater than 700 nm) often penetrates opaque layers more effectively.

In yet another aspect, the measurement results described herein can be used to provide active feedback to a process tool (e.g., lithography tool, etch tool, deposition tool, etc.). For example, values of film thickness, critical dimensions, overlay, etc., determined using the methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement to provide active feedback to etch tools or deposition tools, respectively.

In general, the systems and methods described herein can be implemented as part of the process of off-line or on-tool measurement.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the correction of wafer tilt.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A semiconductor measurement system comprising:
an illumination source configured to generate an amount of illumination radiation incident on a semiconductor wafer at a measurement site at one or more nominal angles of incidence, wherein one or more structures are fabricated on the semiconductor wafer at the measurement site;
a detector configured to detect a first amount of collected radiation from the semiconductor wafer in response to the incident amount of illumination radiation at each of the one or more nominal angles of incidence;
a computing system configured to:
estimate values of one or more actual angles of incidence of the incident amount of illumination radiation with respect to the semiconductor wafer, wherein the values of the one or more actual angles of incidence are different from the one or more nominal angles of incidence; and
estimate a value of a parameter of interest characterizing the one or more structures fabricated on the surface of the semiconductor wafer based at least in part on the detected first amount of collected radiation and the values of the one or more actual angles of incidence.

2. The semiconductor measurement system of claim 1, further comprising:
a wafer orientation measurement subsystem comprising:
an optical illumination source configured to generate an optical illumination beam directed to the surface of the semiconductor wafer at the measurement site; and
an optical detector configured to detect light reflected from the semiconductor wafer in response to the incident optical illumination beam, wherein the
estimating of the values of one or more actual angles of incidence is based on a location of incidence of the detected light on the optical detector.

3. The semiconductor measurement system of claim 1, wherein the estimating of the value of the parameter of interest involves a physics based measurement model or a machine learning based measurement model.

4. The semiconductor measurement system of claim 1, further comprising:
a specimen positioning system configured to orient the semiconductor wafer about a first axis and a second axis at the measurement location, wherein the first and second axes are aligned with the surface of the semiconductor wafer and the second axis is orthogonal to the first axis.

5. The semiconductor measurement system of claim 4, wherein the detector detects the amount of collected radiation from the semiconductor wafer at a plurality of nominal angles of incidence while the specimen positioning system scans the semiconductor wafer about the first axis over a range of nominal angles of incidence, and wherein the estimating of the actual angle of incidence corresponding to each of the plurality of nominal angles of incidence is based on the detected radiation at each of the plurality of nominal angles of incidence.

6. The semiconductor measurement system of claim 1, further comprising:
an illumination pupil aperture configured to direct the amount of illumination radiation onto the semiconductor wafer at a plurality of nominal angles of incidence simultaneously, wherein the detector includes an active surface that resolves incident radiation in a first direction and a second direction orthogonal to the first direction, the detector further configured to resolve the amount of collected radiation by wavelength in the first direction and by angle of incidence in the second direction.

7. The semiconductor measurement system of claim 6, wherein the estimating of the actual angle of incidence corresponding to each of the plurality of nominal angles of incidence is based on the detected radiation at each of the resolved angles of incidence.

8. The semiconductor measurement system of claim 1, wherein the illumination source and the detector are elements of any of a single wavelength ellipsometer, a spectroscopic ellipsometer, a beam profile reflectometer, an x-ray based scatterometer, and a spectroscopic reflectometer.

9. The semiconductor measurement system of claim 1, wherein the one or more structures fabricated on the surface of the semiconductor wafer include one or more film structures, one or more critical dimension structures, or a combination thereof.

10. The semiconductor measurement system of claim 4, the specimen positioning system, comprising:
a two axis wafer stage configured to locate the semiconductor wafer with respect to the illumination source and the detector at any location on the surface of the semiconductor wafer;
a wafer chuck configured to removably couple the semiconductor wafer to the specimen positioning system; and
at least three actuators spaced apart from one another, wherein each of the at least three actuators is mechanically coupled between the wafer chuck and the two axis wafer stage, wherein a direction of extent of each of the at least three actuators is approximately parallel to a direction normal to the surface of the semiconductor wafer when coupled to the wafer chuck.

11. The semiconductor measurement system of claim 10, the specimen positioning system further comprising:
at least three position sensors, each of the at least three position sensors located in close proximity to a corresponding actuator of the at least three actuators, wherein each of the at least three position sensors is configured to measure a displacement in the direction of extent of each corresponding actuator.

12. A semiconductor measurement system comprising:
an illumination source configured to generate an amount of illumination radiation incident on a surface of a semiconductor wafer at a measurement site, wherein one or more structures are fabricated on the semiconductor wafer at the measurement site;
a specimen positioning system configured to orient the semiconductor wafer about a first axis and a second axis at the measurement location, wherein the first and second axes are aligned with the surface of the semiconductor wafer and the second axis is orthogonal to the first axis;
a detector configured to detect a first amount of collected radiation from the semiconductor wafer in response to the incident amount of illumination radiation at a plurality of azimuth angles and a first nominal angle of incidence while the specimen positioning system scans the semiconductor wafer about the first axis and the second axis simultaneously such that the surface of the semiconductor wafer is oriented with respect to the incident amount of illumination radiation over a range of azimuth angles at the first nominal angle of incidence; and
a computing system configured to:
estimate a value of an tilt azimuth angle associated with an alignment between the incident amount of illumination radiation and a feature of the one or more structures fabricated on the semiconductor wafer based on the first amount of collected radiation.

13. The semiconductor structure of claim 12, the detector further configured to detect a second amount of collected radiation from the semiconductor wafer in response to the incident amount of illumination radiation at a first plurality of angles of incidence and the value of the tilt azimuth angle while the specimen positioning system scans the semiconductor wafer about the first axis such that the surface of the semiconductor wafer is oriented with respect to the incident amount of illumination radiation over a first range of angles of incidence at the value of the tilt azimuth angle; and
a computing system configured to:
estimate a value of a tilt angle of incidence associated with the alignment between the incident amount of illumination radiation and the feature of the one or more structures fabricated on the semiconductor wafer based on the second amount of collected radiation.

14. The semiconductor structure of claim 13, the detector further configured to detect a third amount of collected radiation from the semiconductor wafer in response to the incident amount of illumination radiation at a second plurality of angles of incidence and the value of the azimuth tilt while the specimen positioning system scans the semiconductor wafer about the first axis such that the surface of the semiconductor wafer is oriented with respect to the incident amount of illumination radiation over a second range of angles of incidence at the value of tilt azimuth angle, wherein the second range of angles of incidence is smaller than the first range of angles of incidence and includes the tilt angle of incidence; and
a computing system configured to:
estimate a refined value of the tilt angle of incidence associated with the alignment between the incident amount of illumination radiation and the feature of the one or more structures fabricated on the semiconductor wafer based on the third amount of collected radiation.

15. A method comprising:
generating an amount of illumination radiation incident on a semiconductor wafer at a measurement site at one or more nominal angles of incidence, wherein one or more structures are fabricated on the semiconductor wafer at the measurement site;
detecting a first amount of collected radiation from the semiconductor wafer in response to the incident amount of illumination radiation at each of the one or more nominal angles of incidence;
estimating values of one or more actual angles of incidence of the incident amount of illumination radiation with respect to the semiconductor wafer associated with each of the one or more nominal angles of incidence; and
estimating a value of a parameter of interest characterizing the one or more structures fabricated on the surface of the semiconductor wafer based at least in part on the detected first amount of collected radiation and the values of the one or more actual angles of incidence.

16. The method of claim 15, further comprising:
generating an optical illumination beam directed to the surface of the semiconductor wafer at the measurement site; and
detecting light reflected from the semiconductor wafer on an optical detector in response to the incident optical illumination beam, wherein the estimating of the values of one or more actual angles of incidence is based on a location of incidence of the detected light on the optical detector.

17. The method of claim 15, further comprising:
orienting the semiconductor wafer about a first axis and a second axis at the measurement location, wherein the first and second axes are aligned with the surface of the semiconductor wafer and the second axis is orthogonal to the first axis, wherein the amount of collected radiation from the semiconductor wafer is detected at a plurality of nominal angles of incidence while orienting the semiconductor wafer about the first axis over a range of nominal angles of incidence, and wherein the estimating of the actual angle of incidence corresponding to each of the plurality of nominal angles of incidence is based on the detected radiation at each of the plurality of nominal angles of incidence.

18. The method of claim 15, further comprising:
directing the amount of illumination radiation onto the semiconductor wafer at a plurality of nominal angles of incidence simultaneously; and
resolving collected radiation across a detector surface in a first direction according to wavelength and a second direction according to angle of incidence, wherein the estimating of the actual angle of incidence corresponding to each of the plurality of nominal angles of incidence is based on the detected radiation at each of the resolved angles of incidence.

19. A method comprising:
generating an amount of illumination radiation incident on a surface of a semiconductor wafer at a measurement site, wherein one or more structures are fabricated on the semiconductor wafer at the measurement site;
orienting the semiconductor wafer about a first axis and a second axis at the measurement location, wherein the first and second axes are aligned with the surface of the semiconductor wafer and the second axis is orthogonal to the first axis;
detecting a first amount of collected radiation from the semiconductor wafer in response to the incident amount of illumination radiation at a plurality of azimuth angles and a first nominal angle of incidence while orienting the semiconductor wafer about the first axis and the second axis simultaneously; and
estimating a value of an tilt azimuth angle associated with an alignment between the incident amount of illumination radiation and a feature of the one or more structures fabricated on the semiconductor wafer based on the first amount of collected radiation.

20. The method of claim 19, further comprising:
detecting a second amount of collected radiation from the semiconductor wafer in response to the incident amount of illumination radiation at a first plurality of angles of incidence and the value of the tilt azimuth angle while orienting the semiconductor wafer; and
estimating a value of a tilt angle of incidence associated with the alignment between the incident amount of illumination radiation and the feature of the one or more structures fabricated on the semiconductor wafer based on the second amount of collected radiation.

21. The method of claim 20, further comprising:
detecting a third amount of collected radiation from the semiconductor wafer in response to the incident amount of illumination radiation at a second plurality of angles of incidence and the value of the azimuth tilt while orienting the semiconductor wafer, wherein the second range of angles of incidence is smaller than the first range of angles of incidence and includes the tilt angle of incidence; and
estimating a refined value of the tilt angle of incidence associated with the alignment between the incident amount of illumination radiation and the feature of the one or more structures fabricated on the semiconductor wafer based on the third amount of collected radiation.
